(19) United States
(12) Patent Application Publication
(10) Pub. No.: US 2014/0126162 A1
(43) Pub. Date: May 8, 2014

(54) SUBSTRATE INDUCTIVE DEVICE METHODS AND APPARATUS

(71) Applicant: Pulse Electronics, Inc., San Diego, CA (US)

(72) Inventors: Mohammad Saboori, San Diego, CA (US); Vinay Gundotra, San Diego, CA (US); Hamlet Abedmamoore, San Diego, CA (US)

(21) Appl. No.: 13/797,501

(22) Filed: Mar. 12, 2013

Related U.S. Application Data
(60) Provisional application No. 61/723,692, filed on Nov. 7, 2012.

(51) Int. Cl. H05K 1/18; H05K 3/30

(52) U.S. Cl. CPC H05K 1/18; H05K 3/30
USPC 361/748; 174/260; 29/607

(57) ABSTRACT

An improved low cost and highly consistent inductive apparatus. In one embodiment, the low cost and highly consistent inductive apparatus addresses concerns with so called conductive anodic filament (CAF) that occurs within these laminate structures by incorporating surface mountable chip chokes in the underlying circuit design, These conditions that result in undesirable CAF include high humidity, high bias voltage (i.e. a large voltage differential), high-moisture content, surface and resin ionic impurities, glass to resin bond weakness and exposure to high assembly temperatures that can occur, for example, during lead free solder bonding application. Methods of manufacturing and using the aforementioned substrate inductive devices are also disclosed.

### PRIORITY AND RELATED APPLICATIONS

This application claims the benefit of priority to co-owned U.S. Provisional Patent Application Ser. No. 61/723,692 of the same title filed Nov. 7, 2012, the contents of which are incorporated herein by reference in its entirety.

This application is also related to co-owned and co-pending U.S. patent application Ser. No. 11/985,156 filed Nov. 13, 2007 and entitled “Wire-Less Inductive Devices and Methods” which claims priority to U.S. Provisional Patent Application Ser. No. 60/859,120 filed Nov. 14, 2006 of the same title, the contents of each of the foregoing being incorporated herein by reference in its entirety. This application is also related to co-owned and co-pending U.S. Pat. No. 7,982,572 filed Jul. 15, 2009 and entitled “Substrate Inductive Devices and Methods”, which claims priority to U.S. Provisional Patent Application Ser. No. 61/135,243, filed Jul. 17, 2008 of the same title, the contents of each of the foregoing being incorporated herein by reference in its entirety. Furthermore, this application is also related to co-owned and co-pending U.S. patent application Ser. No. 12/876,003 filed Sep. 3, 2010 and entitled “Substrate Inductive Devices and Methods”, the contents of which are incorporated herein by reference in its entirety.

### COPYRIGHT

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

1. Technological Field

The present disclosure relates generally to circuit elements and more particularly in one exemplary aspect to inductors or inductive devices having various desirable electrical and/or mechanical properties, and methods of utilizing and manufacturing the same.

2. Description of Related Technology

A myriad of different configurations of inductors and inductive devices are known in the prior art. One common approach to the manufacture of efficient inductors and inductive devices is the use of a magnetically permeable toroidal core. Toroidal cores are very efficient at maintaining the magnetic flux of an inductive device constrained within the core itself. Typically these cores (toroidal or not) are wound with one or more magnet wire windings thereby forming an inductor or an inductive device.

More recently, improved low cost and highly consistent inductive apparatus and methods for manufacturing, and utilizing, the same have been developed. One example of this is disclosed in co-owned and co-pending U.S. patent application Ser. No. 12/876,003 filed Sep. 3, 2010 and entitled “Substrate Inductive Devices and Methods”, the contents of which are incorporated herein by reference in its entirety, discloses a substrate based inductive device which utilizes inserted conductive pins in combination with plated substrates to replace traditional windings disposed around a magnetically permeable core. In some variations this is accomplished without a header disposed between adjacent substrates while alternative variations utilize a header. In another variation, the substrate inductive devices are incorporated into integrated connector modules. However, as the electronics utilized within, for example, integrated connector modules has miniaturized, issues such as Conductive Anodic Filament (CAF) have become major barriers to implementing these substrate inductive devices. CAF occurs in substrates (such as printed circuit boards) when copper filament forms in the laminate dielectric material between two adjacent conductors or plated through-hole vias under an electrical bias. CAF can be a significant source of electrical failures in these substrate inductive devices.

Accordingly, despite the broad variety of substrate inductive device configurations, there is a salient need for substrate inductive devices that are much more resistant to failures such as CAF. Furthermore, ideally such improved substrate inductive devices will be both: (1) low in cost to manufacture; and (2) offer improved electrical performance over prior art devices. Ideally such a solution would not only offer very low manufacturing cost and improved electrical performance for the inductor or inductive device, but also provide greater consistency between devices manufactured in mass production; i.e., by increasing consistency and reliability of performance by limiting opportunities for manufacturing errors of the device while minimizing failure modes such as CAF. Furthermore, methods and apparatus for incorporating improved inductors or inductive devices into integrated connector modules are also needed.

### SUMMARY

The aforementioned needs are satisfied herein by providing improved substrate inductive device apparatus and methods for manufacturing and using the same.

In a first aspect, a substrate inductive device is disclosed. In one embodiment, the substrate inductive device includes a plurality of substrates, at least one of the substrates including a plurality of chip choke components, the chip choke components allowing for the use of larger toroidal cores than would be possible absent the incorporation of the chip choke components.

In an alternative embodiment, the substrate inductive device includes a plurality of substrates comprising a plurality of ferrite cores, at least one of the substrates including a plurality of chip choke components, the chip choke components configured to reduce the occurrence of conductive anodic filament (CAF) formation.

In a second aspect, a method of manufacturing the aforementioned substrate inductive devices is disclosed. In one embodiment, the method of manufacturing the substrate inductive device includes routing and printing a pair of printed circuit boards; placing a plurality of surface mountable chip chokes on one of the printed circuit boards; placing a plurality of ferrite cores on at least one of the printed circuit boards; and routing a plurality of conductive wires around the plurality of ferrite cores by inserting the conductive wires into a plurality of through hole vias located on the pair of printed circuit boards.

In a third aspect, methods of using the aforementioned substrate inductive devices are disclosed.

In a fourth aspect, a single-port connector which utilizes the aforementioned substrate inductive device is disclosed.

In a fourth aspect, a multi-port connector which utilizes the aforementioned substrate inductive device is disclosed.

In a fifth aspect, a method of manufacturing a single-port connector utilizing the aforementioned substrate inductive device is disclosed.

In a sixth aspect, a method of manufacturing a multi-port connector utilizing the aforementioned substrate inductive device is disclosed.

In a seventh aspect, networking equipment which utilizes the aforementioned multi-port connectors is disclosed.

### BRIEF DESCRIPTION OF THE DRAWINGS

The features, objectives, and advantages of the disclosure will become more apparent from the detailed description set forth below when taken in conjunction with the drawings, wherein:

FIG. 1 is a front view of a prior art substrate inductive device apparatus.

FIG. 2 is a front view of a substrate inductive device, similar to that shown in FIG. 1 that utilizes surface mountable chip-chokes in accordance with the principles of the present disclosure.

FIG. 3 is a logical flow diagram illustrating a first exemplary method for manufacturing the aforementioned substrate inductive device in accordance with the principles of the present disclosure.

Reference is now made to the drawings wherein like numerals refer to like parts throughout.

### DETAILED DESCRIPTION

As used herein, the terms “electrical component” and “electronic component” are used interchangeably and refer to components adapted to provide some electrical and/or signal conditioning function, including without limitation inductive reactors (“choke coils”), transformers, filters, transistors, gapped core toroids, inductors (coupled or otherwise), capacitors, resistors, operational amplifiers, and diodes, whether discrete components or integrated circuits, whether alone or in combination.

As used herein, the term “magnetically permeable” refers to any number of materials commonly used for forming inductive cores or similar components, including without limitation various formulations made from ferrite.

As used herein, the term “signal conditioning” or “conditioning” shall be understood to include, but not be limited to, signal voltage transformation, filtering and noise mitigation, signal splitting, impedance control and correction, current limiting, capacitance control, and time delay.

As used herein, the terms “top”, “bottom”, “side”, “up”, “down” and the like merely connote a relative position or geometry of one component to another, and in no way connote an absolute frame of reference or any required orientation. For example, a “top” portion of a component may actually reside below a “bottom” portion when the component is mounted to another device (e.g., to the underside of a PCB).

Overview

The present disclosure provides, inter cilia, improved low cost and highly consistent inductive apparatus and methods for manufacturing, and utilizing, the same.

More specifically, the present disclosure addresses issues with so-called substrate inductive devices such as conductive anodic filament (CAF) that occurs within similar laminate structures (such as a printed circuit board) under certain conditions. These conditions include high humidity, high bias voltage (i.e. a large voltage differential), high-moisture content, surface and resin ionic impurities, glass to resin bond weakness and exposure to high assembly temperatures that can occur, for example, during lead free solder bonding applications.

In embodiments disclosed herein, a substrate inductive device is disclosed which replaces some of the ferrite cores typically seen in prior art designs with so-called chip chokes. For example, in one embodiment, the present disclosure replaces four (4) traditional common mode chokes with surface mountable chip chokes. The chip choices are advantageous in that they take up much less space than prior art ferrite common mode chokes. Accordingly, by incorporating these chip chokes into, for example, the PoE circuit design known in the prior art, the resultant non-chip choke circuitry can accommodate larger ferrite cores, resulting in larger associated via-to-via and via-to-trace spacing, than would otherwise be possible thereby alleviating issues with, for example, CAR In one embodiment, these chip chokes comprise those choke coil devices disclosed in co-owned U.S. Provisional Patent Application Ser. No. 61/732,698 filed Dec. 3, 2012 and entitled “Choke Coil Devices and Methods of Making and Using the Same”, the contents of which are incorporated herein by reference in its entirety. In addition, by incorporating these surface-mountable chip chokes in the underlying magnetic circuit design the number of through hole vias that need to be filled with conductive wires is cut by roughly half thereby improving manufacturing times and cost associated with these substrate inductive devices.

Methods of manufacturing and using the aforementioned substrate inductive devices are also disclosed.

Exemplary Embodiments

Detailed descriptions of the various embodiments and variants of the apparatus and methods of the present disclosure are now provided.

Substrate Inductive Device Apparatus

It is well known in the electronics industry that conductive anodic filament (CAF) occurs within a laminate structure (such as a printed circuit board) under certain conditions. These conditions include high humidity, high bias voltage (i.e. a large voltage differential), high-moisture content, surface and resin ionic impurities, glass to resin bond weakness and exposure to high assembly temperatures that can occur, for example, during lead free solder bonding application. Typically, CAF forms within the laminate, and at the surface from: (1) via-to-via; (2) via-to-trace; (3) trace-to-trace; and (4) layer-to-layer. Within the context of substrate inductive devices, via-to-via CAF formation is particularly problematic. Furthermore, within the context of substrate inductive devices, such as transformers, the bias voltages that can occur between the primary and secondary windings can be particularly problematic for CAF, especially during high-potential events. In the context of magnetic components for use in, for example, router and switch applications, these magnetic components must meet the CAF and high-voltage potential (HiPot) requirements as specified per IEEE/IPC guidelines.

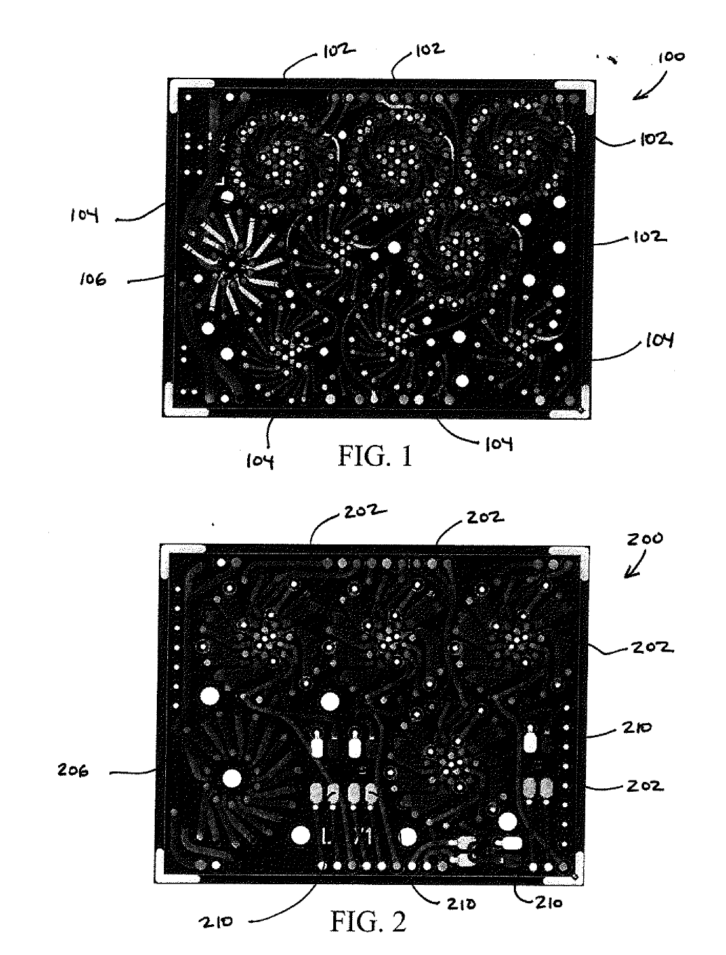

FIG. 1 illustrates an exemplary prior art substrate inductive device 100. The prior art substrate inductive device is manufactured according to the principles discussed in co-owned and co-pending U.S. patent application Ser. No. 12/876,003 filed Sep. 3, 2010 and entitled “Substrate Inductive Devices and Methods”, the contents of which are incorporated herein by reference in its entirety. The substrate inductive device illustrated is for use in a typical Power over Ethernet (PoE) application and includes nine (9) ferrite cores including four (4) transformers 102, four (4) common mode chokes 104 and one (1) PoE choke 106. While the prior art substrate inductive device has generally been adequate in meeting industry standard guidelines with respect to device performance including: (1) return loss; (2) open circuit inductance (OCL); and (3) common mode choke impedance, the prior art design has had difficulty in passing High Potential Voltage (HiPot) and CAF requirements per IEEE/IPC guidelines. The primary reason behind this relatively poor CAF performance has been, inter cilia, the small via-to-via and via-to-trace distances necessary to accommodate each of these nine (9) ferrite cores in an otherwise fixed printed circuit board (PCB) space.

FIG. 2 illustrates a substrate inductive device 200 in accordance with the principles of the present disclosure. Specifically, FIG. 2 illustrates a circuit that is functionally equivalent to the printed circuit board illustrated in FIG. 1; however, the printed circuit board in FIG. 2 addresses the relatively poor CAF performance found in the printed circuit board of FIG. 1. The substrate inductive device exemplary embodiment shown in FIG. 2 is for use in a typical PoE application and includes five (5) ferrite cores and four (4) chip chokes. In one embodiment, the chip chokes will comprise size 1206 two-wire surface mountable chip chokes. However, most transceivers in LAN applications are current mode drive transceivers. In current mode drive, only one of the two differential drivers on the transmitter provides the drive current and the net magnetic flux on the 2-wire surface mountable chip choke is not zero. Accordingly, this causes part of the signal to drop across the 2-wire surface mountable chip choke which results in a lower signal at the primary side of the transformer. Accordingly, in an alternative variant, the 2-wire chip chokes will be replaced with three-wire surface mountable chip chokes. These three-wire chip chokes will resolve this issue in certain LAN applications.

The five (5) ferrite cores are used to make the four (4) transformers 202 and the single PoE choke 206 which serve a similar function as those illustrated in FIG. 1 while the four (4) common mode chokes have been replaced with, for example, the 1206 SMT 2-wire chip chokes 210. As can be seen, the 1206 SMT 2-wire chip chokes take up much less space than the ferrite common mode chokes illustrated in FIG. 1. Accordingly, by incorporating these 1206 SMT 2-wire chip chokes into the PoE circuit design illustrated in FIG. 1, the circuitry shown in FIG. 2 can accommodate larger ferrite cores, and associated larger via-to-via and via-to-trace spacing, than would otherwise be possible. In addition, the number of though hole vias is substantially reduced (on the order of about a half) over the substrate inductive device shown in FIG. 1. The reduced number of through hole vias is resultant from: (1) the larger toroids that can now be used in the substrate inductive device 200; and (2) the fact that prior art wire wound toroids (e.g. common mode chokes) are being obviated in favor of chip chokes. For example, the transformers used in FIG. 2 can be manufactured with ten (10) turns as opposed to the twelve (12) turns needed in the prior art. Furthermore, the PoE choke 206 can now be wound with ten (10) turns instead of the eleven (11) previously needed. Finally, the use of the chip chokes obviates the need entirely for through hole vias.

In one variant of the disclosure, the ferrite cores illustrated in FIG. 2 use a higher permeability material than that shown in FIG. 1 thereby boosting the OCL performance of the embodiment illustrated in FIG. 2. Furthermore, as the spacing between vias and traces has been increased in the embodiment of FIG. 2, manufacturing defects are also significantly decreased thereby avoiding costly rework and/or costly scrapping of substrate inductive device product. Such increased spacing thereby ultimately reducing the component cost of each substrate inductive device, at least with respect to losses experienced as a result of product yield.

Accordingly, the circuitry illustrated in the embodiment illustrated in FIG. 2 provides comparable electrical performance while increasing the spacing, increasing pad size and thereby eliminating the negative effects of CAF formation.

Methods of Manufacture

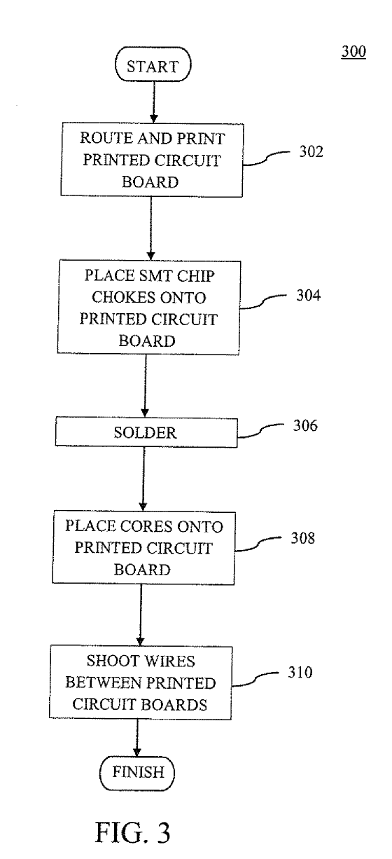

Referring now to FIG. 3, an exemplary method of manufacturing 300 the substrate inductive device of, for example, FIG. 2 is shown and described in detail. At step 302, the printed circuit board is routed and printed in accordance with the principles of the present disclosure. More specifically, the traces and pads used to accommodate, inter alia, the surface mountable chip chokes are printed. The through hole vias used to accommodate the wired connections for the transformer and PoE choke are also fowled.

At step 304, the surface mountable chip chokes are placed onto the printed circuit board. In one embodiment, the printed circuit board has a screen printable solder paste applied thereto. Upon application of the solder paste, the chip chokes are placed onto the solder paste and the underlying printed circuit board pads. Alternatively, the surface mountable chip chokes can be manually placed onto the printed circuit board without the use of solder paste and can be subsequently hand soldered onto the printed circuit board.

At step 306, the surface mountable chip chokes are soldered to the printed circuit board, either by automated processes such as IR reflow, or by hand soldering the surface mountable chip chokes to the printed circuit board.

At step 308, the ferrite cores are placed onto the printed circuit board. In one embodiment, the ferrite cores are secured to one of the printed circuit boards using an epoxy and subsequently inserted into an assembly fixture. The assembly fixture will maintain a fixed distance between the opposite printed circuit board and the cores so as to accommodate thermal expansion during subsequent soldering operations. The use of spacing to accommodate, inter alia, thermal expansion of the ferrite cores is disclosed in co-owned and co-pending U.S. patent application Ser. No. 12/876,003 filed Sep. 3, 2010 and entitled “Substrate Inductive Devices and Methods”, the contents of which were previously incorporated herein by reference in its entirety.

At step 310, the conductive wires that join the substrates and ultimately form the wires for the underlying magnetic cores are placed within their respective conductive vias and soldered. The placement of conductive wires that join the substrates are also disclosed in co-owned and co-pending U.S. patent application Ser. No. 12/876,003 filed Sep. 3, 2010 and entitled “Substrate Inductive Devices and Methods”, the contents of which were previously incorporated herein by reference in its entirety.

It will be recognized that while certain aspects of the invention are described in terms of specific design examples, these descriptions are only illustrative of the broader methods of the invention, and may be modified as required by the particular design. Certain steps may be rendered unnecessary or optional under certain circumstances. Additionally, certain steps or functionality may be added to the disclosed embodiments, or the order of performance of two or more steps permuted. All such variations are considered to be encompassed within the invention disclosed and claimed herein.

While the above detailed description has shown, described, and pointed out novel features of the invention as applied to various embodiments, it will be understood that various omissions, substitutions, and changes in the form and details of the device or process illustrated may be made by those skilled in the art without departing from the invention. The foregoing description is of the best mode presently contemplated of carrying out the invention. This description is in no way meant to be limiting, but rather should be taken as illustrative of the general principles of the invention. The scope of the invention should be determined with reference to the claims.

What is claimed is:

1. A substrate inductive device, comprising:
a plurality of substrates, at least one of the substrates including a plurality of chip choke components, the chip choke components allowing for the use of larger toroidal cores than would be possible absent the incorporation of the chip choke components.

2. The substrate inductive device of claim 1, wherein the substrate inductive device comprises a power over Ethernet (PoE) circuit comprising four (4) chip choke components and five (5) ferrite toroids.

3. The substrate inductive device of claim 2, wherein the chip choke components comprise two-wire surface mountable chip choke components.

4. The substrate inductive device of claim 2, wherein the chip choke components comprise three-wire surface mountable chip choke components.

5. The substrate inductive device of claim 4, wherein the three-wire surface mountable chip choke components are configured to resolve situations in which a net magnetic flux across the chip choke component comprises a non-zero value.

6. The substrate inductive device of claim 2, wherein the use of the four (4) chip choke components allows for a reduction in a number of turns required for the five (5) ferrite toroids.

7. The substrate inductive device of claim 6, wherein the five (5) ferrite toroids comprise four (4) transformers and a PoE choke ferrite toroid.

8. The substrate inductive device of claim 7, wherein the four (4) transformers each comprise ten (10) turns and the PoE choke ferrite toroid comprises eleven (11) turns.

9. The substrate inductive device of claim 8, wherein each of the plurality of turns comprises a conductive wire inserted into a pair of through hole vias.

10. A method of manufacturing a substrate inductive device, comprising:
routing and printing a pair of printed circuit boards;
placing a plurality of surface mountable chip chokes on one of the printed circuit boards;
placing a plurality of ferrite cores on at least one of the printed circuit boards; and
routing a plurality of conductive wires around the plurality of ferrite cores by inserting the conductive wires into a plurality of through hole vias located on the pair of printed circuit boards.

11. The method of manufacturing a substrate inductive device of claim 10, wherein the substrate inductive device comprises a power over Ethernet (PoE) circuit comprising four (4) surface mountable chip chokes and five (5) ferrite cores.

12. The method of manufacturing a substrate inductive device of claim 11, wherein the use of the four (4) surface mountable chip chokes allows for a reduction in a number of turns required for the five (5) ferrite cores.

13. The method of manufacturing a substrate inductive device of claim 12, wherein the five (5) ferrite cores comprise four (4) transformers and a PoE choke ferrite core.

14. The method of manufacturing a substrate inductive device of claim 13, wherein the four (4) transformers each comprise ten (10) turns and the PoE choke ferrite core comprises eleven (11) turns.

15. A substrate inductive device, comprising:
a plurality of substrates comprising a plurality of ferrite cores, at least one of the substrates including a plurality of chip choke components, the chip choke components configured to reduce the occurrence of conductive anodic filament (CAP) formation.

16. The substrate inductive device of claim 15, further comprising a plurality of through holes with respective conductive wires configured to be inserted into the plurality of through holes.

17. The substrate inductive device of claim 16, wherein the inclusion of the plurality of chip choke components increases the through hole to through hole distance versus if these plurality of chip choke components were replaced with ferrite cores.

18. The substrate inductive device of claim 17, wherein the chip choke components comprise two-wire surface mountable chip choke components.

19. The substrate inductive device of claim 17, wherein the chip choke components comprise three-wire surface mountable chip choke components.

20. The substrate inductive device of claim 19, wherein the three-wire surface mountable chip choke components are configured to resolve situations in which a net magnetic flux across the chip choke component comprises a non-zero value.
